(19) United States
(12) Patent Application Publication
(10) Pub. No.: US 2026/0237609 A1
(43) Pub. Date: Aug. 13, 2026

(54) STRUCTURAL MEMBER

(71) Applicant: TOTO LTD., Fukuoka (JP)

(72) Inventors: Kenichi MOTOMURA, Fukuoka (JP); Ryoto TAKIZAWA, Fukuoka (JP)

(73) Assignee: TOTO LTD., Fukuoka (JP)

(21) Appl. No.: 19/410,429

(22) Filed: Dec. 5, 2025

(30) Foreign Application Priority Data
Dec. 23, 2024 (JP) 2024-226287

(51) Int. Cl. H01J 37/32; H01J 9/20

(52) U.S. Cl. CPC H01J 37/32495; H01J 9/20; H01J 37/32467; H01J 2237/0213

(57) ABSTRACT

A structural member including a protective film having high durability against plasma is provided. The structural member 10 includes a base material 100 and a protective film 200 including yttria as a main component, the protective film 200 covering the surface 110 of the base material 100. In a diffraction pattern obtained by analyzing the surface 210 of the protective film 200 using X-ray diffraction, P1/(P1+P2+P3+P4+P5+P6)>0.015 is satisfied, where P1 represents a maximum intensity of a peak attributed to the (622) plane of a cubic crystal structure, P2 represents a maximum intensity of a peak attributed to the (211) plane of a cubic crystal structure, P3 represents a maximum intensity of a peak attributed to the (222) plane of a cubic crystal structure, P4 represents a maximum intensity of a peak attributed to the (400) plane of a cubic crystal structure, P5 represents a maximum intensity of a peak attributed to the (440) plane of a cubic crystal structure, and P6 represents a maximum intensity of a peak attributed to the (541) plane of a cubic crystal structure.

### CROSS-REFERENCE TO RELATED APPLICATION

This application is based upon and claims the benefit of priority from Japanese Patent Application No. 2024-226287, filed on Dec. 23, 2024, the entire contents of which are incorporated herein by reference.

### FIELD

The present invention relates to a structural member.

### BACKGROUND

Durability against plasma is required for members constituting a semiconductor manufacturing apparatus, for example, members such as chamber inner walls and the like. Therefore, structural members having a protective film formed on the surface of a base material have been commonly used as the above members as disclosed in Japanese Patent Laid-Open No. 2007-321183. Materials, such as yttria, are often used as protective films.

### SUMMARY

When base materials are repeatedly processed in a semiconductor manufacturing apparatus, the protective film degrades gradually over time. To reduce the frequency of maintenance for a semiconductor manufacturing apparatus, it is desirable that the protective film has a durability against plasma as high as possible.

The present invention has been made in view of such problems, and an object of the present invention is to provide a structural member comprising a protective film having high durability against plasma.

To solve the above problem, the structural member of the present invention comprises a base material and a protective film including yttria as a main component, the protective film covering the surface of the base material. In a diffraction pattern obtained by analyzing the surface of the protective film using X-ray diffraction, P1/(P1+P2+P3+P4+P5+P6)>0.015 is satisfied, where P1 represents a maximum intensity of a peak attributed to the (622) plane of a cubic crystal structure, P2 represents a maximum intensity of a peak attributed to the (211) plane of a cubic crystal structure, P3 represents a maximum intensity of a peak attributed to the (222) plane of a cubic crystal structure, P4 represents a maximum intensity of a peak attributed to the (400) plane of a cubic crystal structure, P5 represents a maximum intensity of a peak attributed to the (440) plane of a cubic crystal structure, and P6 represents a maximum intensity of a peak attributed to the (541) plane of a cubic crystal structure.

The experiments conducted by the present inventors have demonstrated that when the protective film is formed by using a material containing yttria as a main component, the higher the proportion of the (622) plane of a cubic crystal structure on the surface of the protective film, the higher the durability of the protective film against plasma. Specifically, it has been confirmed that when the above-described proportion is increased to such an extent that the ratio P1/(P1+P2+P3+P4+P5+P6)>0.015 is satisfied, the durability of the protective film against plasma can be sufficiently improved.

According to the present invention, a structural member with sufficient durability against plasma can be provided.

### BRIEF DESCRIPTION OF THE DRAWINGS

FIG. 1 schematically illustrates a cross-section of the structural member;

FIG. 2 is a graph illustrating the relationship between the crystal plane ratio of the protective film and the durability of the protective film against plasma;

FIG. 3 is a graph illustrating an analytical method using X-ray diffraction;

FIG. 4 is a graph illustrating an analytical method using X-ray diffraction;

FIG. 5 is a graph illustrating an analytical method using X-ray diffraction; and

FIG. 6 is a table listing film-forming conditions and the like when forming a protective film.

### DETAILED DESCRIPTION

Hereinafter the present embodiment will be described with reference to attached drawings. For clarity of description, identical reference numerals are used to denote the same elements in all figures, and redundant descriptions are omitted.

The structural member 10 of the present embodiment is configured as a member for a semiconductor manufacturing apparatus, such as a plasma etching apparatus. More specifically, the structural member 10 is a member used for the inner wall of a process chamber of semiconductor manufacturing apparatus. The use of the structural member 10 in the present embodiment is merely an example. The structural member 10 may be a member arranged within the process chamber of semiconductor manufacturing apparatus, such as a focus ring.

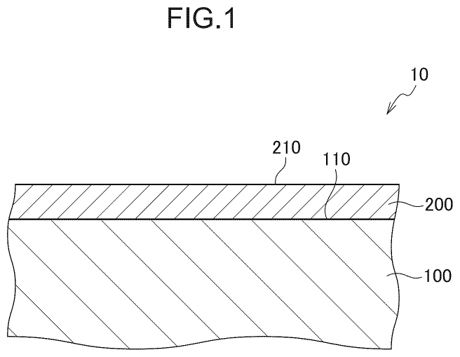

As shown in FIG. 1, the structural member 10 includes a base material 100 and a protective film 200. In a plasma etching apparatus or the like, the surface 210 of the protective film 200 is exposed to the interior of the process chamber. The protective film 200 is formed to protect the surface 110 of the base material 100 from plasma.

The base material 100 is a member forming the primary portion of the structural member 10. In the present embodiment, the base material 100 is a sintered ceramic body including high-purity alumina (Al₂O₃) as a main component, but may be a different ceramic material or member other than a non-ceramic material (for example, a metal member). The surface 110 of the base material 100 is flat in the present embodiment, but may be curved or tapered in portions.

The protective film 200 is formed to protect the base material 100 from plasma as described above. The protective film 200 is formed to cover the entire surface 110 of the base material 100. The protective film 200 is composed of a material including yttria (Y₂O₃) as a main component. The ratio between the number of yttrium (Y) atoms and the number of oxygen (O) atoms in the protective film 200 may be different from the ratio described above. The protective film 200 of the present embodiment is formed by using a physical vapor deposition (PVD) method, but may be formed by another film-forming method.

As used herein, the “main component” refers to the compound contained in the greatest amount in the target object (in this case, protective film 200). More specifically, the “main component” refers to the compound contained in the greatest amount in terms of volume ratio or mass ratio relative to other compounds in the object, as determined by quantitative or semi-quantitative analysis using X-ray diffraction (XRD) on the object.

The proportion of the main component (yttria) in the protective film 200 of the present embodiment is more than 50% by volume or by mass. The proportion may be more than 70%, more than 90%, or may be 100%.

The thickness of the protective film 200 is appropriately adjusted depending on the duration for which durability is required to be maintained and other factors. In the present embodiment, the protective film 200 has a thickness of 15 μm or less.

The present inventors have used yttria as a material for the protective film 200 as in the present embodiment, and have been considering further improvement in the durability of the material against plasma. As a result, it has been confirmed that when the protective film 200 is formed using a material including yttria as a main component, the durability of the protective film 200 against plasma varies depending on the crystal structure of the protective film 200. Specifically, the inventors have found that as the proportion of the (622) plane of a cubic crystal structure on the surface 210 of the protective film 200 increases, the durability of the protective film 200 against plasma improves.

The present inventors prepared multiple samples of the structural member 10 with varying crystal structures for the protective film 200, and assessed durability against plasma for each protective film 200. To evaluate the durability of the protective film 200 against plasma, the surface 210 of each protective film 200 was exposed to a plasma environment using an inductively coupling plasma reactive ion etching (ICP-RIE) system (not shown). The surface 210 was exposed to a plasma atmosphere by the following method.

First, a 4-inch silicon wafer was held by an electrostatic chuck within the chamber of an inductively coupled plasma reactive ion etching system. A sample of the structural member 10, the subject of evaluation, was placed on the silicon wafer. Subsequently, the surface 210 of the protective film 200 was exposed to a plasma environment by generating plasma within the chamber. SF₆ was used as the process gas, and supplied to the chamber at a flow rate of 100 sccm. The pressure in the chamber was adjusted to 0.5 Pa. The time of exposure was 60 minutes. The power output was set to 1,500 W for the ICP coil, and the bias output was turned off (i.e., 0 W). The plasma exposure test for the surface 210 of the protective film 200, performed under the conditions described above, is called the “Standard Plasma Test” below. In the Standard Plasma Test, by turning off the bias output as described above, the plasma is not drawn toward the protective film 200, and hardly used for the etching of the protective film 200. The surface 210 of the protective film 200 is simply exposed to non-directional plasma.

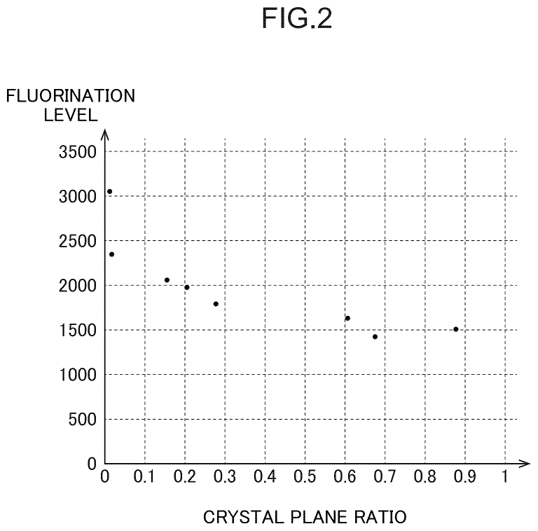

FIG. 2 shows the results of the Standard Plasma Test described above conducted for each of the structural members 10. The “crystal plane ratio” on the horizontal axis of the graph in FIG. 2 is an indicator of the proportion of the (622) plane of a cubic crystal structure in the surface 210 of the protective film 200. As the proportion of the (622) plane of the cubic crystal structure on the surface 210 of the protective film 200 increases, the crystal plane ratio value increases. Specific definitions and calculation methods of the crystal plane ratio will be described later.

The vertical axis of FIG. 2 represents the fluorination level of the protective film 200 after conducting the Standard Plasma Test. The “fluorination level” is an indicator of how deep fluorine atoms, which are part of plasma, penetrate into the interior of the protective film 200. Specific measurement methods of the fluorination level are as follows.

First, while sputtering the surface 210 of the protective film 200 after the Standard Plasma Test using argon, the amount of fluorine atoms present on the surface 210 was continuously measured by X-ray photoelectron spectroscopy (XPS). The measurement was performed for 145 seconds. During the measurement, the proportion of the measured argon concentration in the overall composition (in %) was calculated at each time point, and the integrated value of these proportions was defined as the “fluorination level” of the sample. The higher the durability of the protective film 200 against plasma, the smaller the value of the fluorination level calculated as described above. The fluorination level may be used as an indicator of the durability of the protective film 200 against plasma.

As FIG. 2 clearly shows, the larger the crystal plane ratio value of the protective film 200, the substantially smaller the fluorination level of the protective film 200. For the protective film 200 having a crystal plane ratio of greater than 0.015, the fluorination level is as low as less than 2,500, and sufficient resistance to plasma was verified.

The calculation method of the crystal plane ratio will be described. The crystal plane ratio is calculated from the results of the analysis of the crystal structure of the protective film 200 using X-ray diffraction.

The crystal plane ratio of the protective film 200 was measured using the following method. First, grazing-incidence X-ray diffraction (GIXRD) was performed on the protective film 200 formed on the base material 100 by out-of-plane measurement.

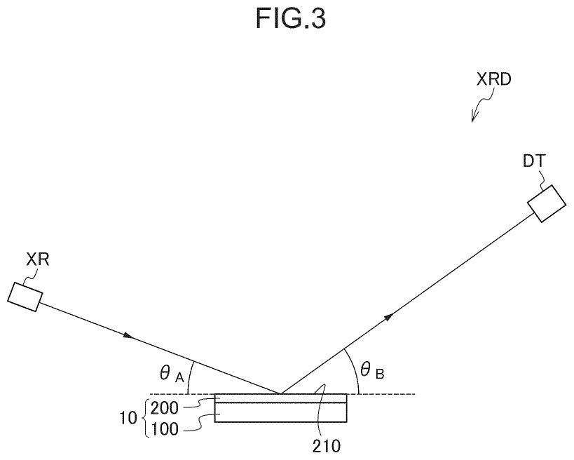

X-ray diffraction is performed using an X-ray diffraction apparatus XRD, as shown in FIG. 3. In the X-ray diffraction apparatus XRD, X-rays of a specific wavelength generated by the X-ray source XR are directed onto the surface 210 of the protective film 200, which is the measurement target. The intensity distribution obtained by detecting the scattered light generated at the surface 210 with the detector DT, i.e., the intensity distribution of the scattered light with respect to the scattering angle θ_{B} (diffraction pattern), corresponds to the crystal structure of the protective film 200. Here, as the incident angle θ_{A} of the X-rays relative to the surface 210 increases, the obtained diffraction pattern corresponds to the crystal structure at deeper positions from the surface 210. In other words, by performing X-ray diffraction while varying the incident angle θ_{A}, the crystal structure at any depth within the protective film 200 can be investigated.

In this embodiment, “SmartLab” manufactured by Rigaku was used as the X-ray diffraction apparatus XRD. The tube voltage was set to 45 kV, the tube current to 200 mA, the scan range to 18 to 80°, the step size to 0.05°, the scan speed to 0.5°/min, and the X-ray incident angle θ_{A} to 0.3°. The sample size was approximately 20 mm×20 mm.

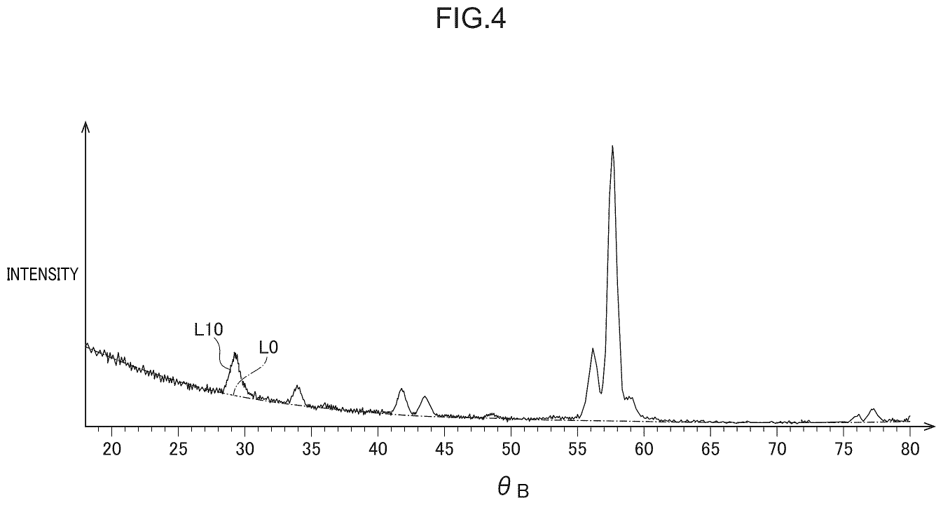

The line L10 in FIG. 4 is an example of the diffraction patterns obtained by analyzing the protective films 200 using X-ray diffraction as described above. This diffraction pattern is also referred to as “the measured diffraction pattern L10” below. A plurality of peaks are observed in the measured diffraction pattern L10, and each peak corresponds to the crystal structure of the material of the protective film 200. For example, the diffraction angles θB corresponding to the maximum of each peak are characteristic of the crystal structure of the protective film 200. The height of each peak corresponds to the proportion of the crystal structure associated with the diffraction angle θB in thr surface (210) of the protective film 200.

The “maximum intensity” of each peak may be used as is, as represented by the maximum intensity on the vertical axis of FIG. 4. However, to determine the crystal plane ratio of the protective film 200 with higher accuracy, the following method is used to obtain the maximum intensity of each peak in the present embodiment.

The dash-dotted line L0 shown in FIG. 4 represents the background intensity in the absence of peaks. The profile of the dash-dotted line L0 can be inferred, for example, from the overall diffraction pattern.

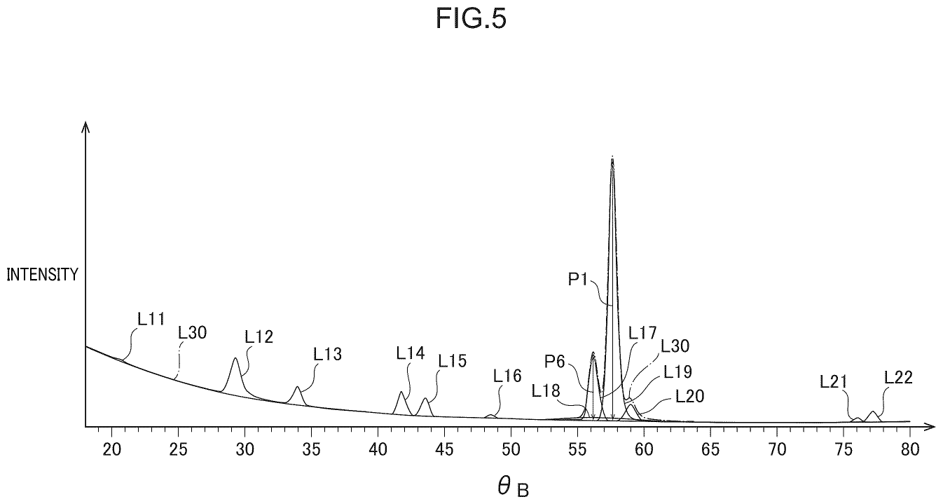

The line L11 shown in FIG. 5 represents a hypothetical diffraction pattern obtained by adding only the peak with the maximum at a diffraction angle θB of 20.72° to the background represented by the dash-dotted line L0 in FIG. 4. The same applies to the lines L12 to L22 shown in FIG. 5, each line representing a hypothetical diffraction pattern obtained by adding only the peak with the maximum at a specific diffraction angle θB to the background.

The diffraction angle θB of the peak of line L12 is 29.23°; the diffraction angle θB of the peak of line L13 is 33.89°; the diffraction angle θB of the peak of line L14 is 41.70°; the diffraction angle θB of the peak of line L15 is 43.50°; the diffraction angle θB of the peak of line L16 is 48.41°; the diffraction angle θB of the peak of line L17 is 56.10°; the diffraction angle θB of the peak of line L18 is 56.70°; the diffraction angle θB of the peak of line L19 is 57.54°; the diffraction angle θB of the peak of line L20 is 58.83°; the diffraction angle θB of the peak of line L21 is 76.04°; and the diffraction angle θB of the peak of line L22 is 77.11°.

The dash-dotted line 30 shown in FIG. 5 is a diffraction pattern obtained by combining all the hypothetical diffraction patterns represented by the lines L11 to L22. This diffraction pattern is also referred to as “approximated diffraction pattern L30” below. When combining multiple hypothetical diffraction patterns, redundant background intensities are not added.

The hypothetical diffraction patterns represented by the lines L11 to L22 are individually adjusted so that the profile of the approximated diffraction pattern L30 obtained by combining them substantially matches the measured diffraction pattern L10 shown in FIG. 4. In other words, by individually adjusting the diffraction angle θB at which the peak reaches the maximum and the height of the peak relative to the background for each line such as L11, the profile of the approximated diffraction pattern L30 is brought closer to the measured diffraction pattern L10. When the two profiles substantially match as a result of such adjustments, each hypothetical diffraction pattern represented by the lines L11 to L22 corresponds to a profile decomposed from the measured diffraction pattern L10 at each diffraction angle θB. Such a process may be performed manually while observing the profile of the approximated diffraction pattern L30, or may be performed automatically using the software functionality.

When the material of the protective film 200 is yttria, the diffraction angle θB of the peak attributed to the (622) plane of the cubic crystal structure is known to be approximately 57.62°. Thus, in the example shown in FIG. 5, the peak attributed to the (622) plane of the cubic crystal structure can be inferred as the peak represented by the line L19. The maximum intensity of the peak, that is, the maximum intensity of the peak relative to the background, is also referred to as the “maximum intensity P1” below.

When the material of the protective film 200 is yttria, the diffraction angle θB of the peak attributed to the (211) plane of the cubic crystal structure is known to be approximately 20.49°. Thus, in the example shown in FIG. 5, the peak attributed to the (211) plane of the cubic crystal structure can be inferred as the peak represented by the line L11. The maximum intensity of the peak, that is, the maximum intensity of the peak relative to the background, is also referred to as the “maximum intensity P2” below.

When the material of the protective film 200 is yttria, the diffraction angle θB of the peak attributed to the (222) plane of the cubic crystal structure is known to be approximately 29.15°. Thus, in the example shown in FIG. 5, the peak attributed to the (222) plane of the cubic crystal structure can be inferred as the peak represented by the line L12. The maximum intensity of the peak, that is, the maximum intensity of the peak relative to the background, is also referred to as the “maximum intensity P3” below.

When the material of the protective film 200 is yttria, the diffraction angle θB of the peak attributed to the (400) plane of the cubic crystal structure is known to be approximately 33.78°. Thus, in the example shown in FIG. 5, the peak attributed to the (400) plane of the cubic crystal structure can be inferred as the peak represented by the line L13. The maximum intensity of the peak, that is, the maximum intensity of the peak relative to the background, is also referred to as the “maximum intensity P4” below.

When the material of the protective film 200 is yttria, the diffraction angle θB of the peak attributed to the (440) plane of the cubic crystal structure is known to be approximately 48.54°. Thus, in the example shown in FIG. 5, the peak attributed to the (440) plane of the cubic crystal structure can be inferred as the peak represented by the line L16. The maximum intensity of the peak, that is, the maximum intensity of the peak relative to the background, is also referred to as the “maximum intensity P5” below.

When the material of the protective film 200 is yttria, the diffraction angle θB of the peak attributed to the (541) plane of the cubic crystal structure is known to be approximately 56.17°. Thus, in the example shown in FIG. 5, the peak attributed to the (541) plane of the cubic crystal structure can be inferred as the peak represented by the line L17. The maximum intensity of the peak, that is, the maximum intensity of the peak relative to the background, is also referred to as the “maximum intensity P6” below.

Among them, only the maximum intensities P1 and P6 are shown in FIG. 5, whereas P2 to P5 are omitted.

Using the maximum intensity values P1 to P6 calculated by the method described above, the crystal plane ratio is determined by the following equation (1).

$$Crystal plane ratio = P 1 / ( P 1 + P 2 + P 3 + P 4 + P 5 + P 6 ) \qquad ( 1 )$$

As described above, the maximum intensity P1 refers to the maximum intensity of the peak attributed to the (622) plane of the cubic crystal structure. Therefore, the crystal plane ratio determined by the above equation (1) can be used as an indicator of the proportion of the (622) plane of the cubic crystal structure on the surface 210 of the protective film 200. As described with reference to FIG. 2, when the crystal plane ratio=P1/(P1+P2+P3+P4+P5+P6)>0.015 is satisfied for the surface 210 of the protective film 200, a sufficient durability against plasma is achieved in the protective film 200.

The patterns shown in FIG. 4 and FIG. 5 are examples for illustrating the definition and the calculation method of the crystal plane ratio and do not correspond to the protective film 200 of the present embodiment.

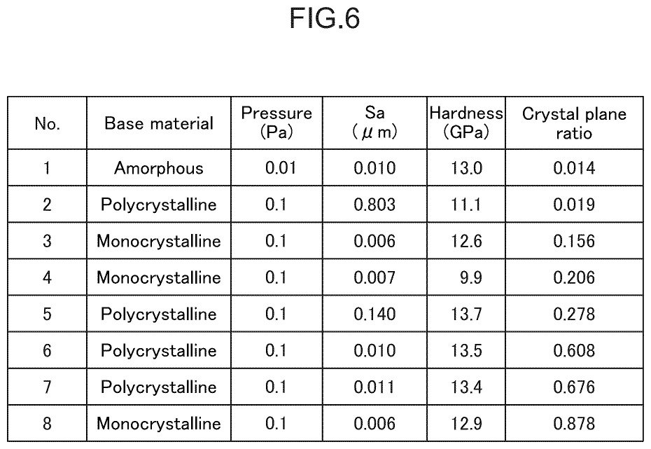

The method and other conditions for producing the samples used for obtaining the data shown in FIG. 2 will be described with reference to FIG. 6. Sample No. 1 in FIG. 6 is a sample prepared under conditions such that the crystal plane ratio on the surface 210 of the protective film 200 was 0.014; Sample No. 2 is a sample prepared under conditions such that the crystal plane ratio on the surface 210 of the protective film 200 was 0.019; Sample No. 3 is a sample prepared under conditions such that the crystal plane ratio on the surface 210 of the protective film 200 was 0.156; and Sample No. 4 is a sample prepared under conditions such that the crystal plane ratio on the surface 210 of the protective film 200 was 0.206.

Sample No. 5 is a sample prepared under conditions such that the crystal plane ratio on the surface 210 of the protective film 200 was 0.278; Sample No. 6 is a sample prepared under conditions such that the crystal plane ratio on the surface 210 of the protective film 200 was 0.608; Sample No. 7 is a sample prepared under conditions such that the crystal plane ratio on the surface 210 of the protective film 200 was 0.676; and Sample No. 8 is a sample prepared under conditions such that the crystal plane ratio on the surface 210 of the protective film 200 was 0.878.

The “Base material” column in the table shown in FIG. 6 shows the structure of the surface 110 of the base material 100, which is made of alumina. In Sample No. 1, the surface 110 of the base material 100 is amorphous. In Samples No. 2, and 5 to 7, the surface 110 of the base material 100 is polycrystalline. In Samples No. 3, 4, and 8, the surface 110 of the base material 100 is monocrystalline.

The protective films 200 of Samples No. 1 to 8 were all formed by a physical vapor deposition (PVD) method. The “pressure” column shown in the table of FIG. 6 represents the pressure in the film forming chamber during the formation of the protective film 200, in particular, the pressure of argon, in units of Pa.

The “Sa” column shown the table of FIG. 6 represents the arithmetic mean height (Sa) of the surface 110 immediately before the protective film 200 is formed, in units of μm.

The “hardness” column shown the table of FIG. 6 represents the indentation hardness of the protective film 200 immediately after film forming, i.e., before conducting the Standard Plasma Test, expressed in units of GPa. The indentation hardness of the protective film 200 was measured by performing a nanoindentation test on the surface 210 of the protective film 200 formed on the base material 100. The indentation hardness of the surface 210 was measured at several sites using a Berkovich indenter with an indentation depth fixed at 200 nm. The respective measurement sites were portions of the surface 210 free of scratches or pits. Provided that the surface 210 is polished to achieve a smooth finish before indentation hardness testing, measurements can be conducted with enhanced precision. The number of measurement sites was 10 or more, and the average of the indentation hardness values obtained from each site was determined as the indentation hardness value of the protective film 200. For specific testing methods, analytical methods, procedures for verifying testing device performance, and requirements for reference samples, methods specified in ISO14577 were employed.

As shown in FIG. 6, Samples No. 1 to 8 differ from one another in terms of the structure and the arithmetic mean height of the surface 110 of the base material 100, and the film-forming conditions for the protective film 200 (specifically, pressures in the film forming chamber), resulting in distinct crystal plane ratios of the protective film 200.

After calculating the crystal plane ratio of Samples No. 1 to 8, the Standard Plasma Test was conducted, yielding the results shown in FIG. 2. The “crystal plane ratio” column in the table of FIG. 6 indicates the calculated crystal plane ratio values of each sample. As described with reference to FIG. 2, it has been confirmed that the greater the crystal plane ratio of the protective film 200, the higher its durability against plasma.

The present embodiment has been described with reference to examples. However, the present disclosure is not limited to these examples. Modifications made to the foregoing examples by those skilled in the art fall within the scope of the present disclosure, provided that they retain the characteristics of the present disclosure. The elements of the foregoing examples, including their configurations, conditions, shapes, and the like, are not limited to those illustrated and can be modified as appropriate. The elements of the foregoing examples can be variously combined, provided that no technical contradiction arises.

What is claimed is:

1. A structural member comprising:
a base material; and
a protective film including yttria as a main component, the protective film covering the surface of the base material, wherein,
in a diffraction pattern obtained by analyzing the surface of the protective film using X-ray diffraction,
P1/(P1+P2+P3+P4+P5+P6)>0.015 is satisfied,
where P1 represents a maximum intensity of a peak attributed to the (622) plane of a cubic crystal structure, P2 represents a maximum intensity of a peak attributed to the (211) plane of a cubic crystal structure, P3 represents a maximum intensity of a peak attributed to the (222) plane of a cubic crystal structure, P4 represents a maximum intensity of a peak attributed to the (400) plane of a cubic crystal structure, P5 represents a maximum intensity of a peak attributed to the (440) plane of a cubic crystal structure, and P6 represents a maximum intensity of a peak attributed to the (541) plane of a cubic crystal structure.

2. The structural member according to claim 1, wherein the protective film is formed by using a physical vapor deposition method.

3. The structural member according to claim 1, wherein the base material comprises alumina as a main component.
